(19) United States
(12) Patent Application Publication
(10) Pub. No.: US 2014/0077831 A1
(43) Pub. Date: Mar. 20, 2014

(54) LINEAR MOTOR FOR A DEVICE FOR TESTING PRINTED CIRCUIT BOARDS AND DEVICE FOR TESTING PRINTED CIRCUIT BOARDS

(71) Applicant: DTG International GmbH, Zurich (CH)

(72) Inventors: Uwe Kordmann, Schonfeld (Großrinderfeld) (DE); Victor Romanov, Wertheim (DE)

(21) Appl. No.: 14/024,534

(22) Filed: Sep. 11, 2013

(30) Foreign Application Priority Data
Sep. 14, 2012 (DE) 20 2012 103 517.0

(51) Int. Cl. H02K 3/26; H02K 41/035; G01R 31/28

(52) U.S. Cl. CPC H02K 3/26; G01R 31/2808; H02K 41/035
USPC 324/750.22; 310/12.21; 310/12.06

(57) ABSTRACT

The invention relates to a linear motor for a device for testing a printed circuit board. The linear motor comprises a stator and a rotor, wherein the stator comprises a row of permanent magnets arranged side by side and alternating in their polarity, and wherein the rotor is formed from a printed circuit board on which conductor paths form magnet coils arranged side by side and each having several windings, which magnet coils, when carrying a current, apply a linear acceleration force to the rotor, so that the rotor is moved relative to the stator, wherein the printed circuit board is folded, so that the several windings of each magnet coil are distributed among several layers of the printed circuit board, which are placed on top of one another by folding the printed circuit board.

The present invention relates to a linear motor for a device for testing printed circuit boards and to such a device for testing printed circuit boards which is provided with such a linear motor.

U.S. Pat. No. 6,664,664 B2 discloses a linear motor having a stator and a rotor, wherein the stator comprises a plurality of permanent magnets arranged in rows side by side and alternating in their polarity and the rotor is formed from a multilayer printed circuit board. The conductor paths form coils, wherein on each layer several windings are provided for each coil and the windings of the individual layers are connected to plated-through holes to form the respective coil. These plated-through holes extend through the entire multilayer printed circuit board. To connect the windings of the several layers to one another in pairs, rows of plated-through holes are arranged side by side. Each of the conductor paths of the windings of the different layers is connected to a different plated-through hole of a defined row of plated-through holes. The ends of the conductor paths of the windings of the individual layers are therefore offset relative to one another and have to be printed using different layouts.

Similar linear motors are further known in which the conductor paths of the different layers can be produced using the same printed images or only a few different printed images. For the paired connection of the windings of different layers, buried vias are used, which are produced by drilling in the multilayer printed circuit board and coating the inner wall of the bore or filling the bore with an electrically conductive metal coating only in the section of the conductor paths to be connected. Using buried vias, conductor paths can be connected in a controlled manner between different inner layers without making the buried vias accessible at the surfaces of the printed circuit board.

Such linear motors having a rotor consisting of a multilayer printed circuit board offer considerable advantages compared to conventional linear motors in which the individual coils are wound from wire. One of the most important advantages lies in the fact that the multilayer printed circuit board can be produced very cost-effectively in large quantities and that the individual coils are moreover formed very precisely. In addition, in the region of a coil, several windings can be arranged spirally relative to one another in each layer, so that coils having a high inductance are obtained. In addition, the side-by-side arrangement of the coils is clearly defined by the printed image with which the printed circuit boards are printed on the circuit board substrate.

A further linear motor with a rotor represented by a printed circuit board is dis-closed by JP 2000228858 A.

Also known for a long time has been the production of coils by printing a conductor path onto a flexible insulating substrate and folding the resultant printed circuit board in such a way that several windings lie on top of one another and form a coil. In this respect, we refer for example to U.S. Pat. No. 2,911,605 submitted for application in 1956, to U.S. Pat. No. 2,943,966 submitted for application in 1954 and to U.S. Pat. No. 5,134,770 submitted for application in 1990. A coil folded in this way is further described in German Utility Model DE 202004007207 U1. These coils produced by means of foldable printed circuit boards are claimed to provide high inductance at a low volume, so that they can offer the desired electric properties in cramped installation conditions.

In devices for testing printed circuit boards, in particular in finger testers which scan the individual contact points of the printed circuit board to be tested successively, the essential criterion for market success is the throughput of printed circuit boards and thus the speed with which the test points of the printed circuit board can be scanned. The testing rate of such a device for testing printed circuit boards is therefore critical for its success. In order to contact the individual circuit board test points in rapid succession, the test probes and therefore the slides to which the test probes are secured have to be traversed quickly. The higher the acceleration forces made available by the motors, the faster the individual circuit board test points can be contacted. There is therefore a need for a further development of the linear motor described above in order to generate higher acceleration forces.

The invention is therefore based on the problem of creating a linear motor for a device for testing printed circuit boards, by means of which high acceleration forces can be generated.

This problem is solved by a linear motor with the features of claim 1. Advantageous further developments are specified in the dependent claims.

The linear motor according to the invention for a device for testing printed circuit boards comprises a stator and a rotor. The stator is formed from a row of magnets arranged side by side and alternating in their polarity. The rotor is formed from a printed circuit board on which conductor paths form magnet coils arranged side by side, each having a plurality of windings which, when conducting a current, apply a linear acceleration force to the rotor, moving the rotor relative to the stator. The printed circuit board is characterised by being folded, so that the plurality of windings of each magnet coil are distributed among several layers of the printed circuit board which are placed on top of one another by the folding of the printed circuit board.

The invention is based on the finding that the vias of the linear motor referred to above and known from U.S. Pat. No. 6,664,664 B2 limit the maximum current which can be conducted by the coils. At the intensive mechanical loads which are present in the device for testing printed circuit boards, where the slides have to be reciprocated fast and for a long time, the printed circuit board is subjected to considerable thermal loads. The vias are produced by drilling the existing laminated printed circuit board, and in this process predetermined existing conductor paths of the different layers are connected to one another. The electric contact between the metal coating of the vias and the conductor paths can not always be obtained with the same quality. This particularly applies to the internal layers, where there is not always a good wetting by the conductive material, resulting in varying contact resistances in these areas. The tolerances are considerable here. At a higher electric resistance, more heat is generated, which can only slowly be removed from the printed circuit board with its poor thermal conductivity. This may result in the melting of the vias and the interruption of the electric contact.

Although the use of buried vias simplifies the production of the printed images of the individual layers, the production of the buried vias is complex and ex-pensive.

These problems are not present in the printed circuit board according to the invention, because the vias or through-plated holes for connecting the individual windings extend through only one layer, which is easily accessible before the folding operation in the production process. The coating of the through-plated holes can be formed with a high quality. In principle, all conductor paths and vias or through-plated holes could even be produced in one operation, resulting in a single-part or monolithic structure. It has to be said, however, that even if the conductor paths and vias or through-plated holes are produced in different steps, the quality of the electric connection between conductor paths on both sides of the foldable printed circuit board is substantially better than in the case of buried vias.

Moreover, the ends of the windings of each layer do not have to be offset relative to one another, resulting in a very simple layout of the printed conductor paths.

As the invention avoids buried vias, the motor according to the invention can be subjected to considerably higher currents, so that higher acceleration forces are obtained.

According to a preferred embodiment, the thickness of the conductor path amounts to at least 75% and preferably at least 100% of the thickness of the electrically insulating substrate of the printed circuit board. In conventional multilayer printed circuit boards, it is impossible for reasons of manufacturing technology to produce in all of the layers conductor paths having a thickness of 50% of the substrate thickness of the individual layers. As a rule, the conductor paths in a multilayer printed circuit board are even thinner. As a result of the great thickness of the conductor path relative to the thickness of the substrate of the printed circuit board, conductor paths having a low resistance and capable of carrying a high current are created while maintaining a very compact design of the rotor.

The conductor paths for example have a thickness of 30 μm to 100 μm. The substrate of the printed circuit board for example has a thickness of 20 μm to 50 μm.

The conductor path is preferably formed from copper or a copper alloy.

The conductor paths preferably have a width of 500 μm to 1000 μm in the region of the coils. The distance between adjacent windings of a coil on a layer is preferably no more than 1 mm, in particular less than 0.25 mm.

The electric connections between the individual layers for connecting the respective windings of a coil are exclusively designed as conductor paths routed over a folding edge of the printed circuit board formed by folding or as through-plated holes which electrically connect the conductor paths on both sides of the respective layer. All conductor paths and through-plated holes of one coil and in particular of all coils are in particular designed monolithic.

An insulating foil can be placed between the individual folded layers. The folded printed circuit board can also be provided with an insulating layer, in particular with an insulating lacquer.

The invention is explained in greater detail below with reference to the drawings, using an embodiment. Of the drawing:

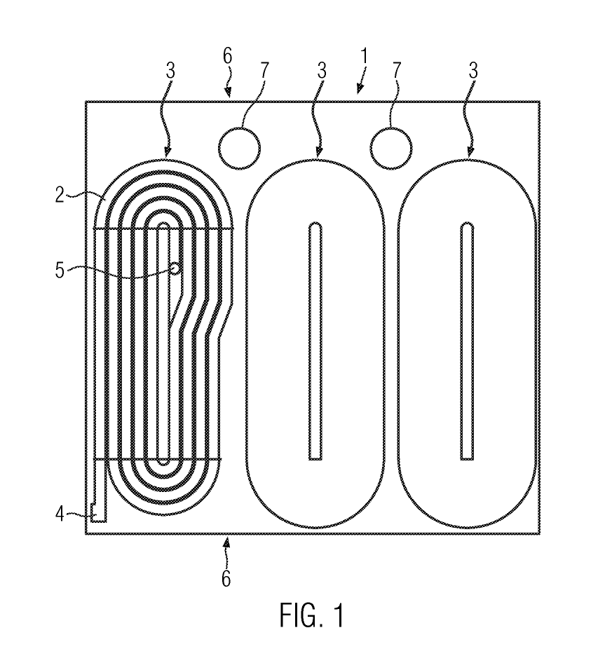

FIG. 1 is a top view of a section of a rotor of the linear motor according to the invention,

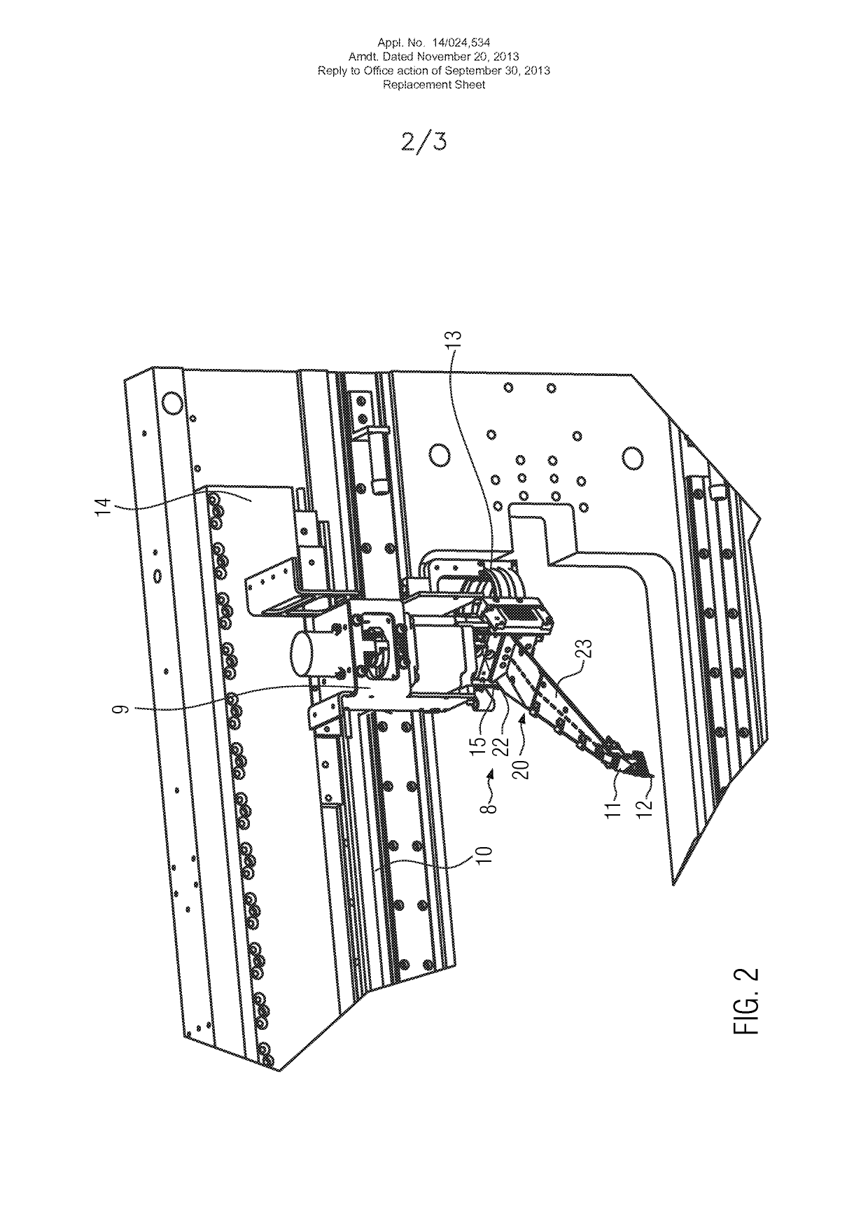

FIG. 2 is a perspective view of a test finger of a device for testing printed circuit boards, which test finger is mounted on a slide dis-placeable on a cross-bar,

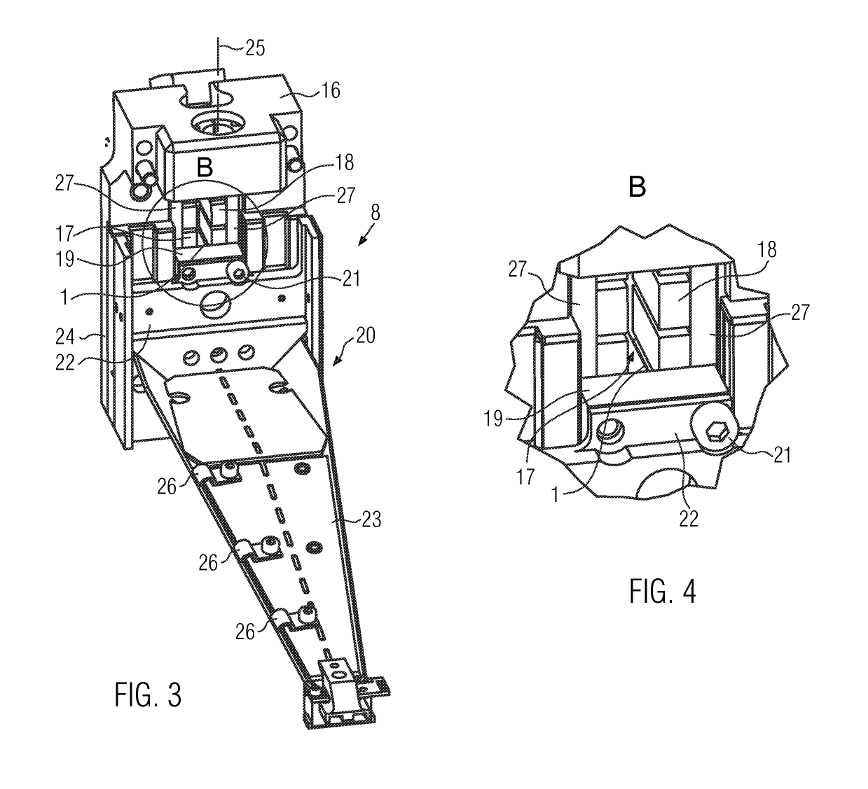

FIG. 3 is an enlarged view of the test finger from FIG. 2, together with a part of the slide, which comprises a linear motor, and

FIG. 4 is an enlarged view of the region from FIG. 3 where the linear motor is located.

The linear motor according to the invention is a further development of the linear motor known from U.S. Pat. No. 6,664,664 B2, which comprises a stator with a plurality of permanent magnets and a rotor represented by a printed circuit board. Unless stated otherwise below, the structure of the linear motor according to the invention corresponds to this known linear motor.

The linear motor according to the invention essentially differs from the known linear motor in that the rotor 1 is represented by a flexible printed circuit board which is folded in such a way that a coil is formed on the rotor 1 by windings which are distributed over several layers of the printed circuit board and which are placed on top of one another.

FIG. 1 is a top view of a section of such a rotor 1, showing only the conductor paths 2 of a single coil 3. Of two further coils 3, only the region where the coils 3 are formed is shown diagrammatically.

The printed circuit board is a thin, flexible printed circuit board, the substrate of which is formed from an electrically non-conducting plastic material such as polyester film with a thickness of e.g. 20 to 55 micrometers. The conductor paths have a thickness of e.g. 30 μm to 100 μm. The thicker the conductor path, the lower is the resistance and the higher is the maximum possible current carrying capacity. The thinner the substrate of the printed circuit board, the more compact and light-weight the rotor can be designed, which is why a substrate as thin as possible is desirable. The thickness of the conductor path is preferably at least 75% of the thickness of the electrically insulating substrate of the printed circuit board and preferably at least 100% of the thickness of the substrate. The thickness of the conductor path in particular exceeds the thickness of the substrate by 20%, by 50%, by 75% or by 100%.

In the region of the coils 3, the conductor paths preferably have a width of 500 μm to 1000 μm. The distance between the edges of adjacent windings of a coil is preferably no more than 1 mm, in particular less than 0.25 mm or less than 0.1 mm.

The windings are in each case formed on the top and the bottom of the folded layer of the printed circuit board. 5 to 20 layers may be folded, so that the number of planes where windings are provided may be 10 to 40. The number of layers is preferably 8 to 15 and in particular 9 to 12.

In the following embodiment 4, 75 windings are provided in one plane. The number of windings per plane can of course vary. At least 3 windings should be provided for each plane. The higher the number of windings in a plane, the greater is the magnetic field obtained with a particular amperage, but the lower is the maximum current carrying capacity. It has therefore been found to be expedient to provide no more than 8 and in particular no more than 6 windings.

FIG. 1 shows an outer surface of the rotor 1 with a topmost plane of windings. At one end of the windings, a pad surface 4 is formed, which acts as a soldered joint, so that the rotor can be electrically connected by means of a soldered joint to a control unit for supplying the coils with an operating current. The rest of the windings is completely coated with an insulating lacquer, so that short circuits, in particular between the conductor paths of layers folded onto one another, are reliable avoided.

The windings are helical, an inner end of the windings being connected to a plated-through hole 5. The plated-through hole 5 extends through the printed circuit board and connects the windings of the coil of one side to the corre-sponding windings of the same coil on the other side of the printed circuit board. The windings are arranged in mirror symmetry relative to the plane of the printed circuit board, being therefore arranged in opposite senses. As the current flows through the windings on both sides of the printed circuit board in opposite directions, the windings of a coil generate a rectified magnetic moment on each of the two sides of the printed circuit board. The outer ends of the windings of the inner layer of a coil do not end at the pad surface, but are connected in pairs, the adjacent windings of two different coils being in each case connected to one another. The conductor path is routed over the folding edge of the folded printed circuit board.

In the illustrated embodiment, the folding edges are formed in the region next to the end faces of the coils 3. In FIG. 1, they are identified by the reference number 6. The individual layers of the printed circuit board are provided with registration bores 7, which are aligned using suitable registration pins in the folding process, so that the individual layers of the printed circuit board are precisely positioned with respect to one another.

The individual coils may be provided with a pad surface 4 at both ends and may be individually connected to the control unit. It is, however, also possible to interconnect the individual coils of a rotor using a series connection, i.e. to connect the outer ends of two adjacent windings electrically on an outer surface of the rotor 1 by means of a conductor path.

The windings of the adjacent coils are designed such that adjacent coils in each case generate an opposite magnetic polarity.

Within the framework of the invention, the coils can also be interconnected in other ways, which are known from the prior art described above.

In the rotor according to the invention, each of the through-plated holes 5 extends through a single layer only. In the production process, the through-plated holes 5 are freely accessible from both sides, so that it can be ensured that they are correctly and completely coated with electrically conductive material. It is in particular even possible to make the conductor paths of the windings of the coil 3 and the through-plated holes 5 monolithic. It is then possible to load the coils with high amperages without risking the melting of the through-plated hole.

A linear motor equipped with a rotor 1 of this type can be used to great ad-vantage in a device for testing electric printed circuit boards, which device comprises test fingers 8 pivotably mounted on a slide 9 capable of traversing along a cross-bar 10 (FIG. 2).

The test finger 8 is pivotably mounted on the slide 9 at one end. At the other end, it is provided with a test probe 11 with a contact pin 12 for successively contacting contact point of a printed circuit board to be tested. For this pur-pose, the contact pin has to be contacted successively with the individual contact points of the printed circuit board, i.e. the contact pin has to be moved to the respective contact points.

The mechanism for moving the test finger 8 comprises a swivel drive 13 for pivoting the test finger 8 about a vertical axis, a horizontal linear drive 14 for moving the slide 9 along the cross-bar 10 and a vertical linear drive 15 for raising and lowering the test finger 8. In the present embodiment, the vertical linear drive 15 is designed as a linear motor equipped with the rotor 1 described above.

In the present embodiment, a printed circuit board to be tested is arranged horizontally. However, testing devices are available in which the printed circuit boards to be tested are arranged vertically. For this reason, the term “vertical” is to be understood in the context of a direction of movement of the test finger or an orientation of an axis of movement or an orientation in a direction per-pendicular to the plane of a printed circuit board to be tested.

A stator 16 is pivotably connected to the slide 9 by means of the swivel drive 13. The stator 16 has a vertically oriented slot region 17, with two rows of permanent magnets 18 arranged opposite side by side. The permanent magnets are located in a U-rail 27 of a magnetic material, in particular a magnetic metal. This U-rail 27 creates a magnetic short-circuit. The permanent magnets are arranged with alternating polarity as known from prior art. Between the two rows of permanent magnets, a slot is bounded in which the rotor 1 is located (FIG. 4). The rotor is integrally joined to a holder 19 to which an elon-gated test finger body 20 is secured by means of a screw connection 21. The test finger body 20 is formed from a substantially vertical, approximately plate-shaped base body 22 and a horizontally oriented finger body 23.

The base body is a metal component, in particular an aluminium component, which is at each of its lateral vertical edges guided on the stator 16 for vertical displacement by means of a linear guide 24 with ball bearings.

The finger body 23 is preferably made of a light-weight, stable plastic material, in particular of a fibre-reinforced plastic material. As the finger body 23 extends horizontally away from an axis of rotation 25 of the stator 16 and sup-ports the test probe 11 at the end remote from the stator 16, the finger body should be as light-weight as possible to reduce the moment of inertia to a min-imum when pivoting the test finger.

Cable guides 26 through which the cables are routed to the test probe are provided on the finger body 23. To simplify the drawings, the cables have been omitted in the figures. The same applies to the cables for connecting the rotor 1 to a control unit (not shown).

If a current is applied to the rotor 1, it generates a force oriented in the vertical direction, which raises or lowers the test finger 8. The rotor according to the invention is capable of carrying strong currents, so that correspondingly strong forces can be applied to the test finger 8. As a result, the test finger 8 can be raised or lowered very fast. The linear motor according to the invention further permits the use of a relatively large and relatively heavy test finger. The larger or longer the test finger 8 is, the larger is the area of a printed circuit board to be tested which can be covered by a test finger. In addition, a long test finger achieves very high relative speeds between the test probe and the printed cir-cult board placed below in a swivel movement, because a small swiveling angle causes a long displacement of the test probe or the printed circuit board to be tested. It is therefore advantageous for the test probe to have a long test finger 8. In the present embodiment, the distance between the axis of rotation 25 of the stator and the contact pin 12 is approximately 100 mm to 200 mm. Owing to the relatively powerful linear motor, the test finger 8 can be raised and lowered very fast, so that approximately 20 to 50 contact points per sec-ond can be scanned with a single contact pin in the case of a commonly used printed circuit board. The linear motor according to the invention therefore makes a substantial contribution to the fast scanning of a large number of contact points, resulting in a high throughput of printed circuit boards. This is the essential criterion for devices for testing non-componented printed circuit boards, because several 10 000 contact points often have to be scanned on individual non-componented printed circuit boards.

In the embodiment shown in FIGS. 2 to 4, only the vertical linear drive 15 is designed with the linear motor according to the invention. It is obviously also possible to provide the swivel drive 13 and/or the horizontal linear drive 14 with the linear motor according to the invention. In order to design the swivel drive 13 with a linear motor according to the invention, the rotor has to have a curved shape if viewed from the top. The permanent magnets of the stator would also have to be provided in a correspondingly curved arrangement. Apart from that, the design of the swivel drive does not differ from that of the vertical linear motor.

In the vertical linear motor described above, guidance is provided by the linear guide 24. As a result, the rotor 1 maintains a defined distance from the permanent magnets of the stator. Within the scope of the invention, however, the rotor 1 can be guided on the stator by means of pneumatic suspension. This would involve the provision of suitable nozzles between the permanent magnets, which apply compressed air to the rotor from both sides, thereby maintaining a constant distance between the rotor and the permanent magnets.

### LIST OF REFERENCE NUMBERS

1 Rotor
2 Conductor paths
3 Coil
4 Pad surface
5 Through-plated hole
6 Folding edge
7 Registration bore
8 Test finger
9 Slide
10 Cross-bar
11 Test probe
12 Contact pin
13 Swivel drive
14 Linear drive
15 Linear drive
16 Stator
17 Slot region
18 Permanent magnet
19 Holder
20 Test finger body
21 Screw connection
22 Base body
23 Finger body
24 Linear guide
25 Axis of rotation
26 Cable guide
27 U-rail

1. Linear motor for a device for testing printed circuit boards, having a stator and a rotor, wherein the stator comprises a row of permanent magnets arranged side by side and alternating in their polarity, and wherein the rotor is formed from a printed circuit board on which conductor paths form magnet coils arranged side by side and each having several windings, which magnet coils, when carrying a current, apply a linear acceleration force to the rotor, so that the rotor is moved relative to the stator,
wherein the printed circuit board is folded, so that the several windings of each magnet coil are distributed among several layers of the printed circuit board, which are placed on top of one another by folding the printed circuit board.

2. Linear motor according to claim 1, wherein the thickness of the conductor path amounts to at least 75% of an electrically insulating substrate of the printed circuit board and preferably at least 100% or at least 150% of the thickness of said substrate.

3. Linear motor according to claim 1, wherein the conductor paths have a thickness of 30 μm to 100 μm.

4. Linear motor according to claim 2, wherein the conductor paths have a thickness of 30 μm to 100 μm.

5. Linear motor according to claim 1, wherein the substrate of the printed circuit board has a thickness of 20 μm to 100 μm or 20 μm to 60 μm.

6. Linear motor according to claim 4, wherein the substrate of the printed circuit board has a thickness of 20 μm to 100 μm or 20 μm to 60 μm.

7. Linear motor according to claim 1, wherein the conductor paths are made of copper or a copper alloy.

8. Linear motor according to claim 6, wherein the conductor paths are made of copper or a copper alloy.

9. Linear motor according to claim 1, wherein the conductor path has a width of 500 μm to 1000 μm at least in the region of the coils.

10. Linear motor according to claim 8, wherein the conductor path has a width of 500 μm to 1000 μm at least in the region of the coils.

11. Linear motor according to claim 1, wherein the edges of adjacent windings of a coil on a layer have a mutual distance of no more than 1 mm, in particular no more than 0.25 mm or no more than 0.1 mm.

12. Linear motor according to claim 10, wherein the edges of adjacent windings of a coil on a layer have a mutual distance of no more than 1 mm, in particular no more than 0.25 mm or no more than 0.1 mm.

13. Linear motor according to claim 1, wherein electric connections between the individual layers for connecting the respective windings of a coil are exclusively designed as conductor paths routed over a folding edge of the printed circuit board formed by folding or as through-plated holes which electrically connect the windings of the coil on both sides of the respective layer.

14. Linear motor according to claim 12, wherein electric connections between the individual layers for connecting the respective windings of a coil are exclusively designed as conductor paths routed over a folding edge of the printed circuit board formed by folding or as through-plated holes which electrically connect the windings of the coil on both sides of the respective layer.

15. Linear motor according to claim 13, wherein all conductor paths and the through-plated holes of one coil and in particular of all coils are designed monolithic.

16. Linear motor according to claim 14, wherein all conductor paths and the through-plated holes of one coil and in particular of all coils are designed monolithic.

17. Linear motor according to claim 1, wherein an insulating foil is placed between the individual folded layers.

18. Linear motor according to claim 16, wherein an insulating foil is placed between the individual folded layers.

19. Linear motor according to claim 1, wherein the printed circuit board is provided with an insulating layer.

20. Linear motor according to claim 18, wherein the printed circuit board is provided with an insulating layer.

21. Linear motor according to claim 1, wherein a pneumatic suspension is formed between the rotor and the stator.

22. Linear motor according to claim 20, wherein a pneumatic suspension is formed between the rotor and the stator.

23. Device for testing printed circuit boards, comprising a slide on which a test finger is pivotably mounted, the test finger being provided at the end remote from the slide with a test probe with a contact pin for contacting contact points of a printed circuit board to be tested, in particular of a non-componented printed circuit board to be tested, wherein a device is provided for the vertical movement of the test finger relative to the slide, wherein the device for the vertical movement of the test finger is a linear motor a stator and a rotor, wherein the stator comprises a row of permanent magnets arranged side by side and alternating in their polarity, and wherein the rotor is formed from a printed circuit board on which conductor paths form magnet coils arranged side by side and each having several windings, which magnet coils, when carrying a current, apply a linear acceleration force to the rotor, so that the rotor is moved relative to the stator, wherein the printed circuit board is folded, so that the several windings of each magnet coil are distributed among several layers of the printed circuit board, which are placed on top of one another by folding the printed circuit board.

24. Device according to claim 23, wherein the test finger is held pivotably on the slide by means of a swiveling device, the swiveling device comprising a curved linear motor.

25. Device according to claim 23, wherein the slide is capable of traversing along a cross-bar by a linear motor.

26. (canceled)
